(19) United States
(12) Patent Application Publication
(10) Pub. No.: US 2019/0190444 A1
(43) Pub. Date: Jun. 20, 2019

(54) SOLAR CELL ARRAY INSPECTION SYSTEM, POWER CONDITIONER, AND SOLAR CELL ARRAY INSPECTION METHOD

(71) Applicant: OMRON Corporation, KYOTO (JP)

(72) Inventors: Akihiko SANO, Uji-shi (JP); Makoto OHASHI, Uji-shi (JP); Yoshihiko YAMAGUCHI, Otsu-shi (JP); Tsuyoshi TAKEUCHI, Aso-shi (JP)

(73) Assignee: OMRON Corporation, KYOTO (JP)

(21) Appl. No.: 16/162,398

(22) Filed: Oct. 17, 2018

(30) Foreign Application Priority Data
Dec. 14, 2017 (JP) 2017-239414

(51) Int. Cl. H02S 50/10; H01L 31/042

(52) U.S. Cl. CPC H02S 50/10; H01L 31/042

(57) ABSTRACT

A solar cell array inspection system includes a measurement part configured to measure a characteristic curve which is an I-V curve or a P-V curve of a solar cell array including a plurality of strings when a current from each of the strings is input through a blocking diode; and a determination part configured to search for an inflection point in the characteristic curve measured by the measurement part, determine whether the state of the solar cell array is an abnormal state in which at least one string has an abnormality based on the results of searching for an inflection point, and notify a user of the determination result.

### CROSS-REFERENCE TO RELATED APPLICATION

This application claims the priority benefit of Japan Patent Application No. 2017-239414, filed on Dec. 14, 2017. The entirety of the above-mentioned patent application is hereby incorporated by reference herein and made a part of this specification.

### BACKGROUND

### Technical Field

The disclosure relates to a solar cell array inspection system, a power conditioner, and a solar cell array inspection method.

### Description of Related Art

In order to inspect (recognize) the state of a solar cell array, I-V curves of strings constituting the solar cell array are measured using a device called an I-V curve tracer or the like. In addition, the technology in which the state of each string is automatically evaluated from measurement results of the I-V curves of the strings has also been developed (for example, Patent Document 1—Japanese Laid-Open No. 2015-173519).

According to the technology described in Patent Document 1, those who do not have sufficient knowledge regarding I-V curve measurement can also inspect the state of the solar cell array. However, in a conventional inspection method in which an I-V curve is measured for each string, only when an I-V curve is measured the same number of times as the number of strings constituting the solar cell array for each inspection of the state of the solar cell array, and the plurality of I-V curves measured are compared, it is possible to check whether the solar cell array is in a normal state.

### SUMMARY

A first embodiment of the disclosure is characterized in that a solar cell array inspection system of the disclosure includes a measurement part configured to measure a characteristic curve which is an I-V curve or a P-V curve of a solar cell array including a plurality of strings when a current from each of the strings is input through a blocking diode; and a determination part configured to search for an inflection point in the characteristic curve measured by the measurement part, determine whether the state of the solar cell array is an abnormal state in which at least one string has an abnormality based on the results of searching for an inflection point, and notify a user of the determination results.

In addition, according to a seventh embodiment of the disclosure, a solar cell array inspection method causes a computer to execute: a determination step of analyzing an I-V curve, which is an I-V curve of a solar cell array including a plurality of strings, measured when a current from each of the strings is input through a blocking diode, and determining whether the state of the solar cell array is an abnormal state in which at least one string has an abnormality; and a notification step of notifying a user of the determination results of the state of the solar cell array according to the determination step.

In addition, according to an eighth embodiment of the disclosure, a solar cell array inspection method causes a computer to execute: a determination step of combining and analyzing I-V curves of strings of a solar cell array including a plurality of strings by addition and subtraction, and determining whether the state of the solar cell array is an abnormal state in which at least one string has an abnormality; and a notification step of notifying a user of the determination results of the state of the solar cell array according to the determination step.

### BRIEF DESCRIPTION OF THE DRAWINGS

FIG. 1 is a schematic configuration diagram of a solar cell array inspection system according to one embodiment of the disclosure.

FIG. 2 is a flowchart of a state determination process that is performed by a determination device of the solar cell array inspection system according to the embodiment.

FIG. 3 includes diagrams (A) and (B) explaining an abnormality detection principle of the solar cell array inspection system according to the embodiment.

FIG. 4 includes diagrams (A) to (F) for explaining details of an abnormality type decision process.

FIG. 5 includes diagrams (A) to (D) for explaining details of the abnormality type decision process.

FIG. 6 includes diagrams (A) to (D) for explaining details of the abnormality type decision process.

FIG. 7 includes diagrams (A) to (F) for explaining details of a number of failed strings determination process.

FIG. 8 is a diagram for explaining a modified example of the solar cell array inspection system according to the embodiment.

### DESCRIPTION OF THE EMBODIMENTS

The disclosure has been made in view of the above problems and the disclosure provides a solar cell array inspection system and a solar cell array inspection method through which it is possible to check whether a solar cell array is in a normal state in a shorter time, and a power conditioner that can be used as a component of such a solar cell array inspection system.

In a characteristic curve (an I-V curve or a P-V curve) of a solar cell array measured when a current from each of the strings of the solar cell array is input through a blocking diode, an inflection point appears when the strings as a whole are not normal. Therefore, a user (such as an inspector) of the solar cell array inspection system can check whether the solar cell array is in a normal state in one characteristic curve measurement (in a shorter time than when characteristic curve measurement is performed for each string).

According to a second embodiment of the disclosure, as a determination part of the solar cell array inspection system, a determination part that determines whether the state of a solar cell array is an abnormal state based on the remaining inflection points obtained by excluding inflection points present in characteristic curves of solar cell arrays which are in a normal state, measured by the measurement part, from found inflection points may be used. When this determination part is used, it is possible to obtain a solar cell array inspection system that can accurately inspect a state of a solar cell array in which there is inherently an inflection point on a characteristic curve (such as a solar cell array in which the numbers of solar cell modules of strings are not the same).

In addition, according to a third embodiment of the disclosure, the solar cell array inspection system may have a configuration “in which when it is determined that the state of a solar cell array is an abnormal state, the determination part compares a voltage value of each inflection point on a characteristic curve measured at a current time by the measurement part with a voltage value of each inflection point on a characteristic curve measured previously by the measurement part, decides whether an abnormality causing each inflection point on the characteristic curve measured at the current time is a temporary abnormality or a non-temporary abnormality, and incorporates the decision result into the determination results that are notified of the user.” If such a configuration is used, for example, when the fact that an abnormality that has occurred is a temporary abnormality (reduction in output due to shade) is notified, inspection of the solar cell array can be terminated without performing additional inspection.

According to a fourth embodiment and a fifth embodiment of the disclosure, the solar cell array inspection system may have a configuration in which “the determination part estimates the number of strings (and the number of clusters (fifth embodiment)) in which an abnormality has occurred among a plurality of strings from positions and the number of inflection points present on the I-V curves measured by the measurement part, and incorporates the estimated number into the determination results that are notified of the user.”

In addition, according to a sixth embodiment of the disclosure, a power conditioner according to an embodiment of the disclosure includes the measurement part of the solar cell array inspection system according to any one of first embodiment to fifth embodiment; and a blocking diode that supplies a current from each string of the solar cell array to the measurement part. Therefore, according to the power conditioner, it is possible to easily realize the solar cell array inspection system according to the above embodiment of the disclosure.

According to the solar cell array inspection method of the seventh embodiment, it is possible to check whether the solar cell array is in a normal state in one characteristic curve measurement (in a shorter time than when characteristic curve measurement is performed for each string).

According to the solar cell array inspection method of the eighth embodiment, since comparison of a plurality of I-V curves or the like is not necessary, it is possible to check whether the solar cell array is in a normal state in a shorter time than when a characteristic curve is measured for each string. Here, as long as I-V curves of the strings used in the solar cell array inspection method are measured almost at the same time, they may not be measured through a blocking diode.

According to the disclosure, it is possible to check whether a solar cell array is in a normal state in a shorter time than before.

Embodiments of the disclosure will be described below with reference to the drawings.

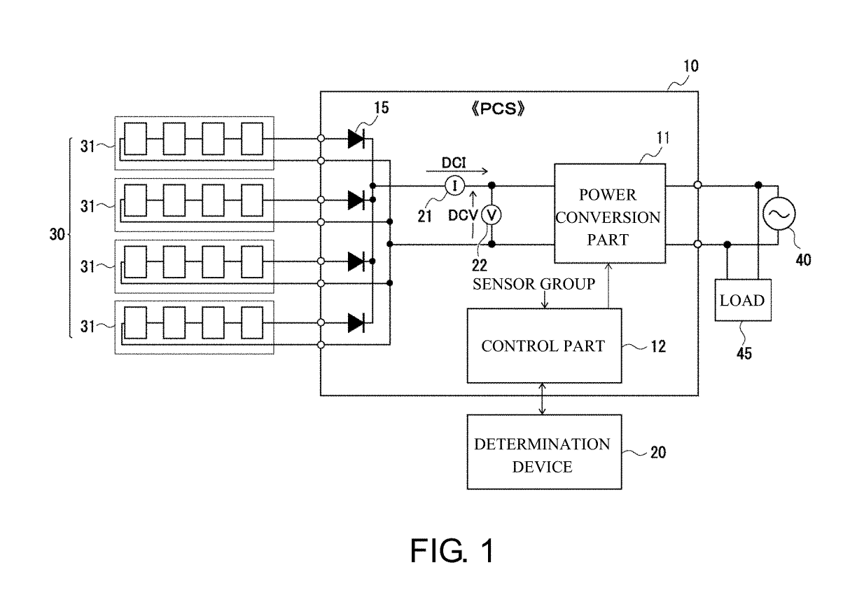

FIG. 1 shows a schematic configuration of a solar cell array inspection system according to one embodiment of the disclosure.

The solar cell array inspection system according to the present embodiment is a system for inspecting a state of a solar cell array 30 including a plurality of strings 31, and includes a power conditioner (PCS) 10 and a determination device 20. Here, the string 31 is a solar cell unit in which a plurality of solar cell modules including one or more (generally, 1 to 3) clusters and a plurality of bypass diodes are connected in series.

The PCS 10 according to the present embodiment is a device that is connected to the solar cell array 30, a system 40, and a load 45 and then used. As shown, the PCS includes a plurality of (four, in FIG. 1) blocking diodes 15 to which an output current of a specific string 31 is input, a power conversion part 11, and a control part 12.

The power conversion part 11 is a part which includes a DC/DC converter and a DC/AC converter and converts DC power into AC power. As shown, the power conversion part 11 and the blocking diodes 15 are connected so that a sum of currents that passed through the blocking diodes 15 is input to the power conversion part 11. In addition, in the PCS 10, a current sensor 21 configured to detect a sum of currents that passes through the blocking diodes 15 and a voltage sensor 22 configured to detect a voltage between input terminals of the power conversion part 11 are provided. Here, a sensor (not shown) other than the sensors 21 and 22 may be provided in the PCS 10.

The control part 12 is a part including a processor (such as a CPU, and a microcontroller), a gate driver, and a communication interface circuit for communication with the determination device 20. Outputs of various sensors including the current sensor 21 and the voltage sensor 22 are input to the control part 12, and the control part 12 performs a general process and an I-V curve measuring process based on information from various sensors.

The general process performed by the control part 12 is a process of controlling the power conversion part 11 so that maximum power is taken out from the solar cell array 30 and converted into a desired alternating current.

The I-V curve measuring process is a process performed by the control part 12 when an instruction regarding I-V curve measurement is issued from the determination device 20. During the I-V curve measuring process, the control part 12 measures an input voltage DCV and an input current DCI of the power conversion part 11 while changing an operating point voltage (input voltage DCV of the power conversion part 11) under control of the power conversion part 11 and thus measures an I-V curve of the solar cell array 30. Then, the control part 12 provides measurement results of I-V curves (a plurality of combinations of a measured voltage value and a current value) to the determination device 20 and ends the I-V curve measuring process.

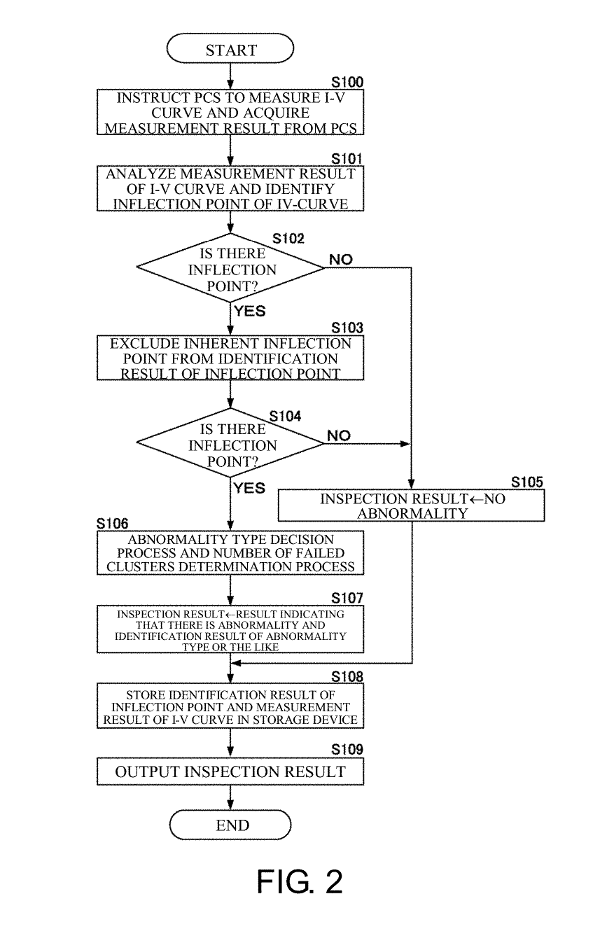

The determination device 20 is a computer configured to perform a state inspection process of the procedure shown in FIG. 2. The determination device 20 may be a general computer (such as a laptop and a desktop computer) that is programmed so that it can perform the state inspection process or a device that is manufactured for use as a component of the solar cell array inspection system. In addition, the determination device 20 may be connected to the PCS 10 by a cable or may be connected to the PCS 10 via the Internet or the like.

When the operation of the solar cell array inspection system starts, in the state determination device 20, open-circuit voltages of the clusters of the solar cell array 30, the number of strings 31 constituting the solar cell array 30, the number of solar cell modules constituting the strings 31, and the number of clusters (generally, 3) constituting the solar cell module are set.

Details of the state inspection process will be described below.

The state inspection process is a process that is started by the determination device 20 (a processor in the determination device 20) when a predetermined instruction is given.

As shown, the determination device 20 that has started the state inspection process first instructs the PCS 10 (the control part 12) to measure an I-V curve (Step S100). Then, the determination device 20 acquires processing results (measurement results of an I-V curve) of the I-V curve measuring process performed by the control part 12 in response to the instruction from the PCS 10 (Step S100).

Here, the PCS 10 (the control part 12) can be provided with a function of measuring an I-V curve and storing it therein when a predetermined condition (when the time reaches a set time, when the generated power is set a power or higher, or the like) is satisfied, and the process of Step S100 may be a process of acquiring the I-V curve stored in the PCS 10 from the PCS 10.

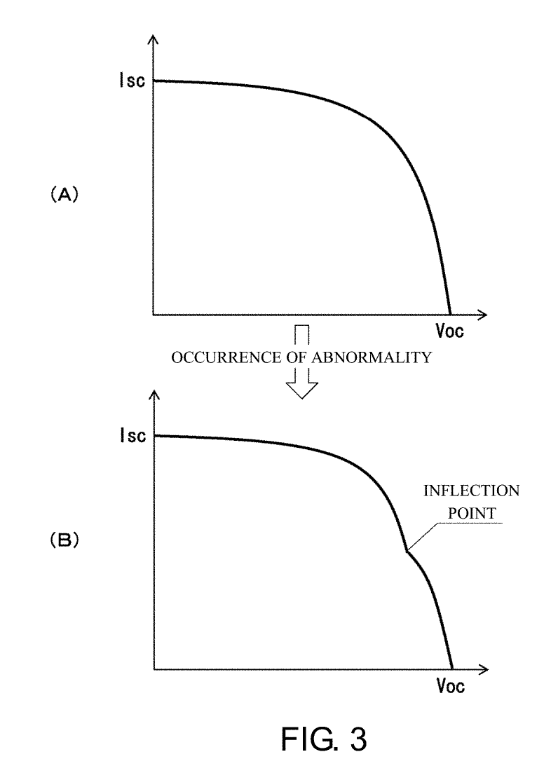

When the strings 31 of the solar cell array 30 have the same configuration and no abnormality has occurred in any of the strings 31, the I-V curve measured by the PCS has no inflection point as shown in the diagram (A) of FIG. 3. Further, when an abnormality has occurred in any of the strings 31, an inflection point appears in the I-V curve measured by the PCS 10 as shown in the diagram (B) of FIG. 3.

Basically, the state inspection process (FIG. 2) is a process of determining whether the state of the solar cell array 30 is abnormal when the I-V curve as shown in the diagram (B) of FIG. 3 is obtained. However, when the numbers of solar cell modules of the strings 31 of the solar cell array 30 are not the same, even if all of the strings 31 are not abnormal, the I-V curve measured by the PCS 10 has an inflection point. Therefore, simply, when the occurrence of an abnormality is determined according to whether there is an inflection point, the state may be erroneously determined in some cases.

In addition, in the strings 31, temporary abnormalities such as a reduction in output due to shade and non-transitory (permanent) abnormalities such as a cluster failure may occur. Here, a cluster failure refers to a phenomenon in which an output of a solar cell module is reduced due to a disconnection in the solar cell module or an abnormality in a cell (a component of a cluster) in the solar cell module.

When it is determined whether an abnormality that has occurred in the string 31 is a temporary abnormality or a non-temporary abnormality, if the abnormality that has occurred is a temporary abnormality, inspection of the solar cell array can be terminated without performing additional inspection. Therefore, it is desirable for the state inspection process to determine whether an abnormality that has occurred is a temporary abnormality or a non-temporary abnormality.

The processes of Steps S101 to S109 in this state inspection process are realized based on the above concepts.

In detail, the determination device 20 that has completed the process of Step S100 analyzes the measurement results of the I-V curve, and thus searches the I-V curve for an inflection point (Step S102). More specifically, the determination device 20 performs the following process in Step S102.

The determination device 20 first generates a d²I/dV²−V curve obtained by second-order differentiating the I-V curve. Next, the determination device 20 performs a first process in which a voltage value at which a “d²I” value of the generated d²I/dV²−V curve is a preset threshold value or higher is set as a voltage value of the inflection point. Here, the reason why such a process is performed is that, since noise is included in the d²I/dV²−V curve, it is difficult to obtain an accurate “0” crossing point (an inflection point on the I-V curve) from the d²I/dV²−V curve.

Then, when the voltage value of the inflection point is not identified in the first process, the determination device 20 provides a processing result indicating that there is no inflection point on the I-V curve, and ends the process of Step S102. On the other hand, in the first process, when voltage values of one or more inflection points are identified, the determination device 20 identifies current values on the I-V curve at the voltage values of the inflection points, and stores the fact that there is an n-th inflection point at I-V coordinates indicated by the identified current value and voltage value. Then, the determination device 20 provides such pieces of information (presence of one or more inflection points and I-V coordinates of the inflection points) as a processing result and ends the process of Step S101.

When no inflection point is found in the process of Step S101 (NO in Step S102), the determination device 20 provides an inspection result indicating that there is no abnormality in any of the strings 31 of the solar cell array 30 (Step S105). Next, the determination device 20 stores the identification result of the inflection point (in this case, the result indicating that there is no inflection point) and the measurement results of the I-V curve in association with an inspection date and time (a date and time at which the state inspection process was performed) in a storage device (such as an internal memory and an HDD) in the determination device 20 (Step S108).

Then, the determination device 20 outputs the inspection result (Step S109), and provides a user with notification that there is no abnormality in any of the strings 31 of the solar cell array 30, and ends the state inspection process. Here, the process of Step S109 performed by the determination device 20 according to the present embodiment is a process of displaying a message indicating that there is no abnormality in any of the strings 31 of the solar cell array 30 on a display of the determination device 20. However, the process of Step S109 may be another process (for example, a process of printing out an inspection result, a process of outputting an inspection result using audio, and a process of performing transmission to another device connected via a network).

In addition, when an inflection point is found in the process of Step S101 (YES in Step S102), the determination device 20 excludes inherent inflection points from the identification result of the inflection points (the processing result of the process of Step S101) (Step S103).

Here, an inherent inflection point is an inflection point that is present inherently on the I-V curve (measured by the PCS 10) of the solar cell array 30 (even if there is no abnormality in any of the strings 31). Here, the determination device 20 can perform an inherent inflection point identifying process in which an inherent inflection point is identified and stored in a storage device in the determination device 20. The inherent inflection point identifying process is a process in which processes corresponding to the processes of Steps S100, S101, and S108 of the state inspection process are sequentially performed. Therefore, although detailed description thereof will be omitted, the user causes the determination device 20 to perform the inherent inflection point identifying process when the solar cell array 30 is in a normal state. Hereinafter, the I-V curve indicated by the measurement result stored in the storage device of the determination device 20 according to the inherent inflection point identifying process will be referred to as a normal I-V curve.

When there is no inflection point as a result of excluding the inherent inflection points (NO in Step S104), the determination device 20 performs processes after Step S105. That is, as in the case in which no inflection point is found in the process of Step S101, the determination device 20 provides an inspection result indicating that there is no abnormality in any of the strings 31 of the solar cell array 30 and stores the identification result of the inflection point and the measurement results of the I-V curve in association with an inspection date and time in the storage device in the determination device 20. Then, the determination device 20 outputs the inspection result and then ends a state determination process.

When there are no inherent inflection points and when an inflection point remains even if inherent inflection points are excluded (YES in Step S104), the determination device 20 performs an abnormality type decision process and a number of failed strings determination process (Step S106).

Basically, the abnormality type decision process is a process in which, regarding inflection points identified according to the current state determination process, according to whether an inflection point has a voltage value which can be regarded as the same as the voltage value of the inflection point included in the identification result of the inflection points according to a previous state determination process, it is decided whether an abnormality causing the inflection point is a non-temporary abnormality or a temporary abnormality.

Details of the abnormality type decision process will be specifically described below with reference to the drawings.

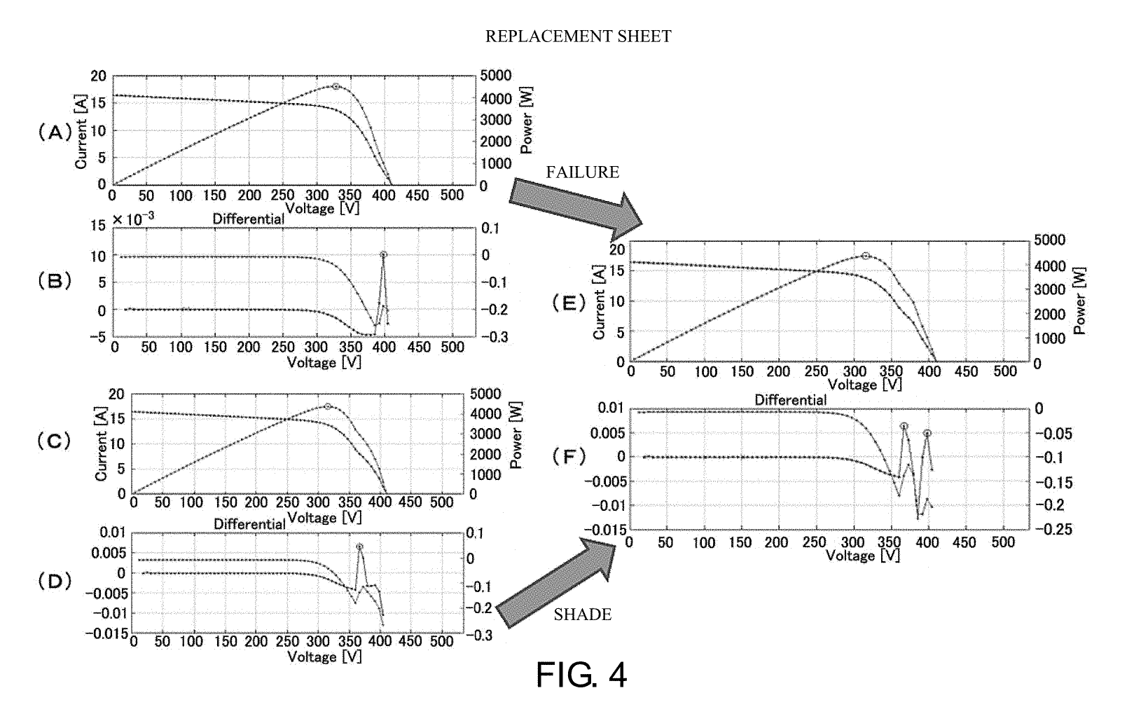

When one cluster of a certain string 31 of the solar cell array 30 fails, an I-V curve measured by the PCS 10 is shown in the diagram (A) of FIG. 4 and the first-order differentiation result and the second-order differentiation result of the I-V curve are shown in the diagram (B) of FIG. 4. As can be clearly understood from the drawing, when one or more clusters of a certain string 31 of the solar cell array 30 fail, an I-V curve having one inflection point is obtained.

In addition, also if an output of a certain string 31 of the solar cell array 30 decreases due to shade, the I-V curve measured by the PCS 10 has one inflection point as shown in the diagram (C) of FIG. 4 (refer to the first-order differentiation result and the second-order differentiation result of the diagram (D) of FIG. 4).

Thus, when a cluster failure and a reduction in output due to shade occur at the same time, the I-V curve measured by the PCS 10 has two inflection points as shown in the diagram (E) of FIG. 4 (refer to the first-order differentiation result and the second-order differentiation result of the diagram (F) of FIG. 4).

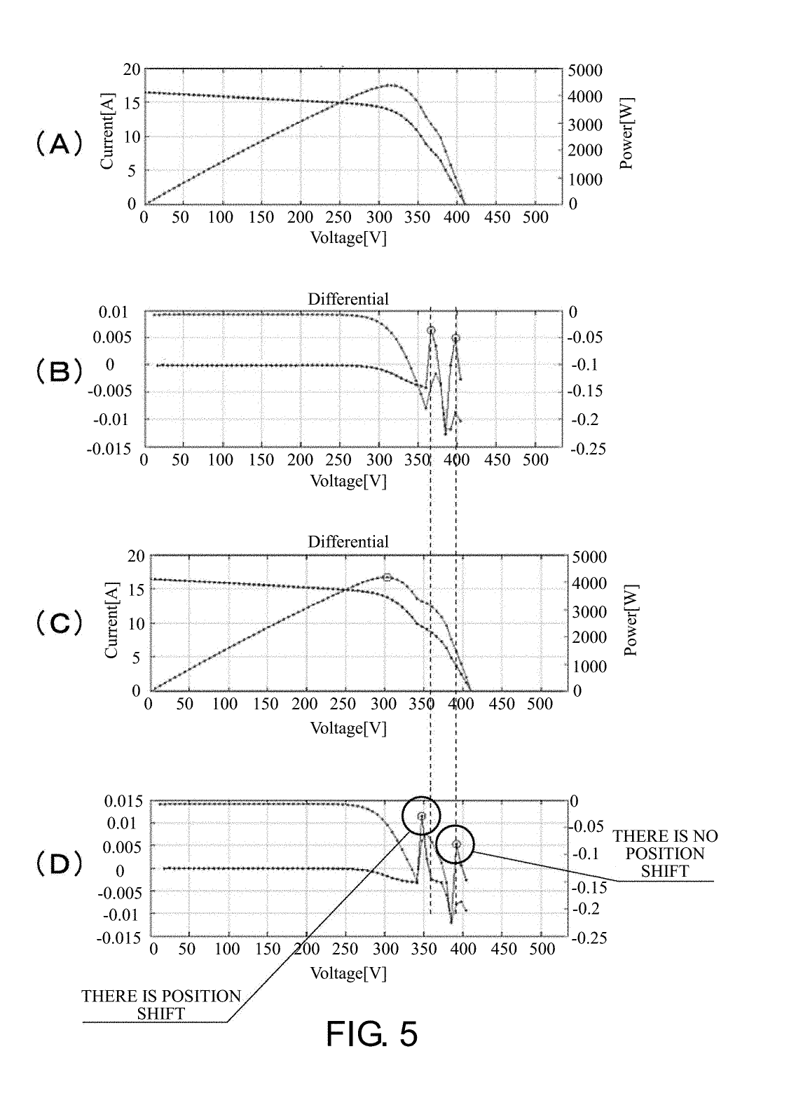

In this manner, since a temporary abnormality and a non-temporary abnormality can occur at the same time, it is difficult to decide whether an abnormality that has occurred is a non-temporary abnormality or a temporary abnormality from one I-V curve (the diagram (E) of FIG. 4). However, when am inflection point is caused by a cluster failure, as shown in the diagrams (A) to (D) of FIG. 5, inflection points (peaks) appear at the same position in two consecutive state determination processes in many cases. Here, the I-V curve shown in the diagram (A) of FIG. 5 shows a simulation result and two curves shown in the diagram (B) of FIG. 5 show the first-order differentiation result and the second-order differentiation result of the I-V curve shown in the diagram (A) of FIG. 5. The I-V curve shown in the diagram (C) of FIG. 5 is an I-V curve measured after waiting for the position of the shade to change after the I-V curve of the diagram (A) of FIG. 5 is measured. Two curves shown in the diagram (D) of FIG. 5 show the first-order differentiation result and the second-order differentiation result of the I-V curve shown in the diagram (C) of FIG. 5.

On the other hand, when an inflection point is caused by shade, as shown in the diagrams (A) to (D) of FIG. 5, the position of the inflection point shifts with the elapse of time. Therefore, basically, in the abnormality type decision process of the above details/procedure, it is possible to decide whether an abnormality causing each inflection point is a non-temporary abnormality or a temporary abnormality.

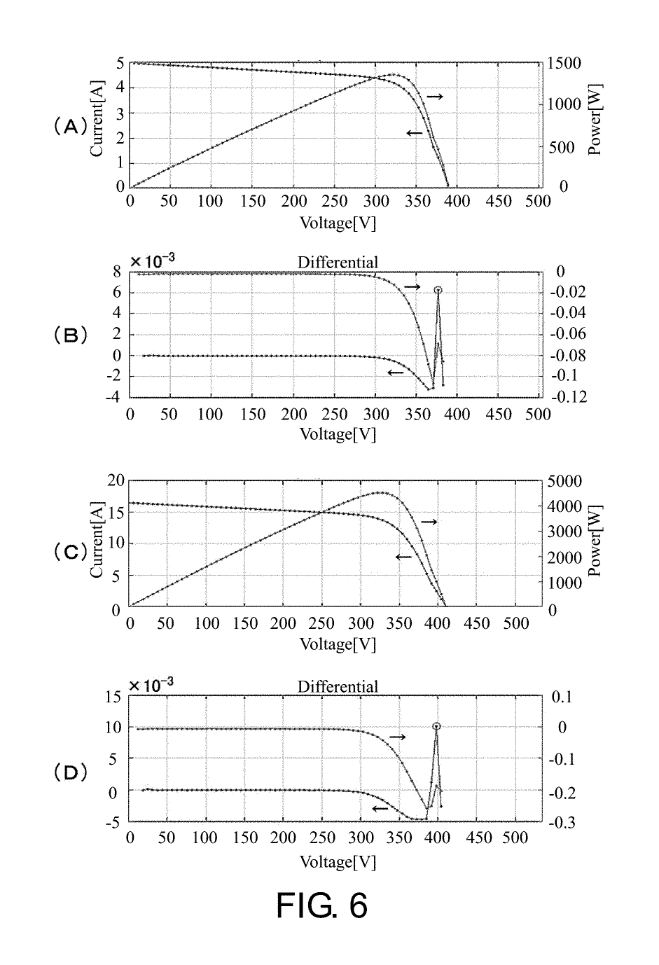

However, when an amount of sunlight varies greatly, the position of the inflection point due to a cluster failure also shifts. Specifically, the diagrams (A) and (C) of FIG. 6 show simulation results of the I-V curve under conditions in which an amount of sunlight of the solar cell array 30 in which one cluster has failed is 300 W/m² and 1,000 W/m². In addition, the diagram (B) of FIG. 6 shows the first-order differentiation result and the second-order differentiation result of the I-V curve shown in the diagram (A) of FIG. 6. The diagram (D) of FIG. 6 shows the first-order differentiation result and the second-order differentiation result of the I-V curve shown in the diagram (C) of FIG. 6.

As can be clearly understood from the diagrams (A) to (D) of FIG. 6, when an amount of sunlight varies greatly, the position of the inflection point due to the cluster failure also shifts. Therefore, when only voltage values are compared, there is a risk of the type of abnormality that has occurred being erroneously decided. Therefore, in the solar cell array inspection system according to the present embodiment, when short-circuit currents of two I-V curves to be compared are greatly different (that is, when there is a possibility of amounts of sunlight being largely different), the abnormality type decision process in which the type of fault occurring is decided in the following procedure is utilized in the determination device 20.

When short-circuit currents of two I-V curves to be compared are greatly different, the determination device 20 divides a voltage value of each inflection point on an I-V curve measured at a current time by an open-circuit voltage of the I-V curve, and thus calculates a normalized voltage value (voltage ratio) of each inflection point. In addition, the determination device 20 divides a voltage value of each inflection point on an I-V curve to be compared by an open-circuit voltage of the I-V curve and thus calculates a normalized voltage value of each inflection point. Then, the determination device 20 compares the normalized voltage values to decide the type of fault that has occurred.

According to the process of such procedures, even if amounts of sunlight are different, it is possible to decide accurately the type of fault that has occurred. Specifically, for example, as shown in the following table, an open-circuit voltage Voc of an I-V curve of the diagram (A) of FIG. 6 is 389.41 V and a voltage Va of the inflection point on the I-V curve is 377.43 V. In addition, an open-circuit voltage of Voc of an I-V curve of the diagram (C) of FIG. 6 is 411.22 V, and a voltage Va of the inflection point on the I-V curve is 398.57 V which is higher than 377.43 V by 20 V or more. On the other hand, normalized voltage values (voltage ratio Va/Voc) regarding the I-V curves match as shown in the following table. Therefore, according to the above processing procedure, even if amounts of sunlight are different, it is possible to decide accurately the type of fault that has occurred.

TABLE 1

| Amount of sunlight | 300 W/m² | 1,000 W/m² |
|---|---|---|
| Voc | 389.41 [V] | 411.22 [V] |
| Va | 377.43 [V] | 398.57 [V] |
| Va/Voc | 0.9692 | 0.9692 |

Returning to FIG. 2, description of the state determination process continues. The number of failed strings determination process (Step S106) is a process in which it is decided whether each inflection point is caused by a cluster failure based on the voltage value of each inflection point on the measured I-V curve and for the inflection point caused by the cluster failure, the number of failed clusters is decided based on the current value.

Hereinafter, details of the number of failed strings determination process will be described using a case in which the solar cell array 30 includes three strings 31 composed of 14 solar cell modules (the number of clusters is “3”) (hereinafter referred to as an array of interest 30) as an example. Here, the nominal maximum output operating voltage of each solar cell module of the array of interest 30 is about 30 V. In addition, the amount of sunlight during each I-V curve measurement to be described below is the same as the amount of sunlight during measurement of a normal I-V curve (an I-V curve indicated by the measurement result stored in the determination device 20 according to the inherent inflection point identifying process).

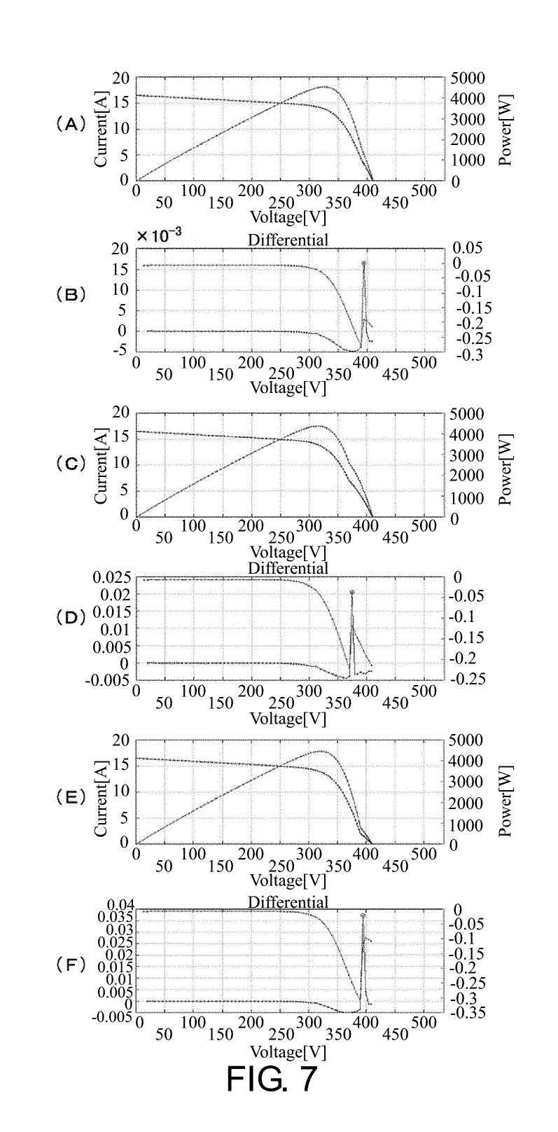

While only one solar cell module fails, when an I-V curve of the array of interest 30 is measured by the PCS 10, the I-V curve shown in the diagram (A) of FIG. 7 is obtained. The first-order differentiation result and the second-order differentiation result of the I-V curve are shown in the diagram (B) of FIG. 7. That is, when only one solar cell module fails, on the I-V curve of the array of interest 30, an inflection point appears at a voltage that is lower than the open-circuit voltage by about 30 V (=the open-circuit voltage of the solar cell module).

When two solar cell modules of the same string 31 fail, the I-V curve of the array of interest 30 is as shown in the diagram (C) of FIG. 7. That is, as can be clearly understood from the first-order differentiation result and the second-order differentiation result of the I-V curve shown in the diagram (D) of FIG. 7, when two solar cell modules of the same string 31 fail, on the I-V curve of the array of interest 30, an inflection point appears at a voltage that is lower than the open-circuit voltage by about 60 V (≅the nominal maximum output operating voltage of the solar cell module×2).

When one solar cell module fails in each of two strings 31, the I-V curve of the array of interest 30 is as shown in the diagram (E) of FIG. 7, and the first-order differentiation result and the second-order differentiation result of the I-V curve are as shown in the diagram (F) of FIG. 7. That is, when one solar cell module fails in each of two strings 31, on the I-V curve of the array of interest 30, an inflection point appears at a voltage that is lower than the open-circuit voltage by about 30 V (≅the open-circuit voltage of the solar cell module).

As described above, the determination device 20 operates when the open-circuit voltage of the cluster is set. Therefore, when the I-V curve in which “the open-circuit voltage−the voltage value of the inflection point” appears to be M (M is a natural number) times the open-circuit voltage of the cluster is obtained, it is possible to decide that M clusters of the same string 31 have failed.

In addition, when only a cluster failure has occurred, a current amount at the inflection point voltage Va decreases by the output current amount of one string at the voltage Va×the number of failed strings from the current amount at the voltage Va of the normal I-V curve. The output current amount of one string at the voltage Va can be calculated by dividing the current amount at the voltage Va of the normal I-V curve by the number of strings. Basically, the number of failed strings determination process is a process in which the total number of failed clusters and the number of strings in which a cluster failure occurred are decided based on the above principle.

However, actually, the amount of sunlight when the state determination process is performed is not the same as the amount of sunlight during normal I-V curve measurement in many cases. Therefore, the number of failed strings determination process is a process in which, when the open-circuit voltage and the short-circuit current of the I-V curve obtained in the process of Step S100 are denoted as Voc1 and Isc1, respectively, and the open-circuit voltage and the short-circuit current of the normal I-V curve are denoted as Voc0 and Isc0, respectively, the voltage and the current at the inflection point are multiplied by “Voc0/Voc1” and “Isc0/Isc1,” respectively, and then the total number of failed clusters, and the number of strings in which a cluster failure occurred are decided in the process of the above procedure/details.

The determination device 20 that has completed the process of Step S106 (the abnormality type decision process and the number of failed strings determination process) provides an inspection result indicating that there is an abnormality and the processing result (a decision result of an abnormality type and the like) of Step S106 (Step S107). Then, the determination device 20 performs the processes of Steps S108 and S109 and then ends the state determination process.

As described above, the solar cell array inspection system according to the present embodiment can check whether the solar cell array 30 is in a normal state in one I-V curve measurement. Therefore, according to the solar cell array inspection system of the present embodiment, it is possible to check whether the solar cell array 30 is in a normal state in a shorter time than when I-V curve measurement is performed for each string 31. In addition, the solar cell array inspection system has a function of notifying a user whether an abnormality that has occurred is a temporary abnormality (a reduction in output due to shade) or a non-temporary abnormality. Therefore, according to the solar cell array inspection system, when the temporary abnormality is notified of, inspection of the solar cell array can be terminated without performing additional inspection.

### MODIFIED EXAMPLES

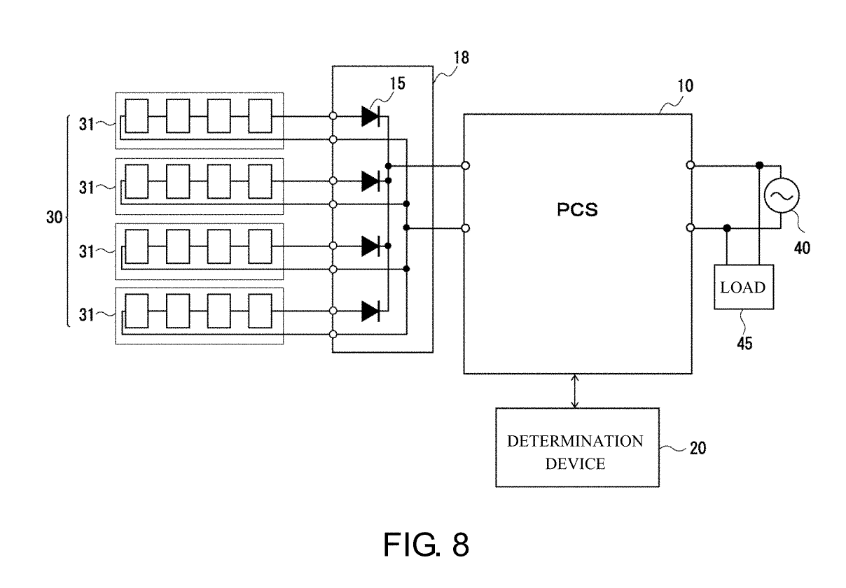

The solar cell array inspection system according to the above embodiment can have various modifications. For example, as shown in FIG. 8, the solar cell array inspection system may be modified into a system configured to measure an I-V curve of the solar cell array 30 based on the output of the solar cell array 30 aggregated in a junction box 18 including the blocking diode 15 therein.

In addition, when an inflection point appears in the I-V curve, an inflection point also appears in the P-V curve. Therefore, the solar cell array inspection system may be modified into a system configured to inspect a state of the solar cell array 30 based on the P-V curve. The solar cell array inspection system may be modified into a system having only an inspection function of the solar cell array 30 or a system in which the control part 12 of the PCS 10 has a function as the determination device 20.

In order to prevent erroneous determination due to a difference in amounts of sunlight, during the abnormality type decision process, the same normalization as during the number of failed strings determination process may be performed, and during the number of failed strings determination process, the same normalization as during the abnormality type decision process may be performed. During each process, normalization of which details are different from the above may be performed, and the state determination process (FIG. 2) may be modified to a process in which both or either of the number of failed strings determination process and the abnormality type decision process is not performed.

In addition, by combining a plurality of I-V curves measured almost at the same time, the same I-V curve as that measured by the PCS 10 (that is, an I-V curve through which it is possible to determine whether the solar cell array is in a normal state according to the presence of an inflection point or the like) can be obtained. In addition, even if the remaining I-V curves are subtracted from the combined results of some of the plurality of I-V curves measured almost at the same time, it is possible to obtain an I-V curve through which it is possible to determine whether the solar cell array is in a normal state according to the presence of an inflection point or the like. Therefore, the state determination process may be modified into a process in which a process of combining a plurality of I-V curves measured almost at the same time by addition and subtraction is performed in Step S101. Here, according to the state determination process modified as above, it is possible to check whether the solar cell array is in a normal state without comparing the plurality of I-V curves or the like. Therefore, it is possible to check whether the solar cell array is in a normal state within a shorter time than before.

### APPENDIX

In order to make it possible to compare constitutional features of the disclosure with the configuration of the embodiment, constitutional features of the disclosure according to independent embodiments will be described below with reference numerals in the drawings.

### First Embodiment

A solar cell array inspection system comprising:

measurement parts 11 and 12 configured to measure a characteristic curve which is an I-V curve or a P-V curve of a solar cell array 30 including a plurality of strings 31 when a current from each of the strings 31 is input through a blocking diode 15; and

a determination part 20 configured to search for an inflection point in the characteristic curve measured by the measurement parts 11 and 12, determine whether the state of the solar cell array 30 is an abnormal state in which at least one string 31 has an abnormality based on the results of searching for an inflection point, and notify a user of the determination result.

### Seventh Embodiment

A solar cell array inspection method causing a computer to execute:

determination steps S100 to S107 of analyzing an I-V curve, which is an I-V curve of a solar cell array 30 including a plurality of strings 31, measured when a current from each of the strings 31 is input through a blocking diode 15, and determining whether the state of the solar cell array 30 is an abnormal state in which at least one string has an abnormality; and

a notification step S109 of notifying a user of the determination results of the state of the solar cell array according to the determination step.

### Eighth Embodiment

A solar cell array inspection method causing a computer to execute:

determination steps S101 to S107 of combining and analyzing I-V curves of strings 31 of a solar cell array 30 including a plurality of strings 31 by addition and subtraction, and determining whether the state of the solar cell array 30 is an abnormal state in which at least one string has an abnormality; and

a notification step S109 of notifying a user of the determination results of the state of the solar cell array according to the determination step.

What is claimed is:

1. A solar cell array inspection system comprising:
a measurement part configured to measure a characteristic curve which is an I-V curve or a P-V curve of a solar cell array including a plurality of strings when a current from each string is input through a blocking diode; and
a determination part configured to search for an inflection point in the characteristic curve measured by the measurement part, determine whether a state of the solar cell array is an abnormal state in which at least one string has an abnormality based on an inflection point searching result, and notify a user of a determination result.

2. The solar cell array inspection system according to claim 1,
wherein the determination part determines whether the state of the solar cell array is the abnormal state based on the remaining inflection point obtained by excluding an inflection point present in the characteristic curve of the solar cell array which is in a normal state, measured by the measurement part, from found inflection points.

3. The solar cell array inspection system according to claim 1,
wherein, when it is determined that the state of the solar cell array is the abnormal state, the determination part compares a voltage value of each inflection point on the characteristic curve measured at a current time by the measurement part with a voltage value of each inflection point on the characteristic curve measured previously by the measurement part, decides whether an abnormality causing each inflection point on the characteristic curve measured at the current time is a temporary abnormality or a non-temporary abnormality, and incorporates a decision result into the determination result that is notified of the user.

4. The solar cell array inspection system according to claim 2,
wherein, when it is determined that the state of the solar cell array is the abnormal state, the determination part compares a voltage value of each inflection point on the characteristic curve measured at a current time by the measurement part with a voltage value of each inflection point on the characteristic curve measured previously by the measurement part, decides whether an abnormality causing each inflection point on the characteristic curve measured at the current time is a temporary abnormality or a non-temporary abnormality, and incorporates a decision result into the determination result that is notified of the user.

5. The solar cell array inspection system according to claim 1,
wherein the determination part estimates the number of strings in which an abnormality has occurred among the plurality of strings from positions and the number of inflection points present on the I-V curve measured by the measurement part, and incorporates the estimated number into the determination result that is notified of the user.

6. The solar cell array inspection system according to claim 2,
wherein the determination part estimates the number of strings in which an abnormality has occurred among the plurality of strings from positions and the number of inflection points present on the I-V curve measured by the measurement part, and incorporates the estimated number into the determination result that is notified of the user.

7. The solar cell array inspection system according to claim 3,
wherein the determination part estimates the number of strings in which an abnormality has occurred among the plurality of strings from positions and the number of inflection points present on the I-V curve measured by the measurement part, and incorporates the estimated number into the determination result that is notified of the user.

8. The solar cell array inspection system according to claim 4,
wherein the determination part estimates the number of strings in which an abnormality has occurred among the plurality of strings from positions and the number of inflection points present on the I-V curve measured by the measurement part, and incorporates the estimated number into the determination result that is notified of the user.

9. The solar cell array inspection system according to claim 1,
wherein the determination part estimates the number of strings and the number of clusters in which an abnormality has occurred among the plurality of strings from positions and the number of inflection points present on the I-V curve measured by the measurement part, and incorporates the estimated number into the determination result that is notified of the user.

10. The solar cell array inspection system according to claim 2,
wherein the determination part estimates the number of strings and the number of clusters in which an abnormality has occurred among the plurality of strings from positions and the number of inflection points present on the I-V curve measured by the measurement part, and incorporates the estimated number into the determination result that is notified of the user.

11. The solar cell array inspection system according to claim 3,
wherein the determination part estimates the number of strings and the number of clusters in which an abnormality has occurred among the plurality of strings from positions and the number of inflection points present on the I-V curve measured by the measurement part, and incorporates the estimated number into the determination result that is notified of the user.

12. The solar cell array inspection system according to claim 4,
wherein the determination part estimates the number of strings and the number of clusters in which an abnormality has occurred among the plurality of strings from positions and the number of inflection points present on the I-V curve measured by the measurement part, and incorporates the estimated number into the determination result that is notified of the user.

13. A power conditioner comprising:
the measurement part of the solar cell array inspection system according to claim 1; and
the blocking diode that supplies the current from each string of the solar cell array to the measurement part.

14. A power conditioner comprising:
the measurement part of the solar cell array inspection system according to claim 2; and
the blocking diode that supplies the current from each string of the solar cell array to the measurement part.

15. A power conditioner comprising:
the measurement part of the solar cell array inspection system according to claim 3; and
the blocking diode that supplies the current from each string of the solar cell array to the measurement part.

16. A power conditioner comprising:
the measurement part of the solar cell array inspection system according to claim 4; and
the blocking diode that supplies the current from each string of the solar cell array to the measurement part.

17. A power conditioner comprising:
the measurement part of the solar cell array inspection system according to claim 5; and
the blocking diode that supplies the current from each string of the solar cell array to the measurement part.

18. A power conditioner comprising:
the measurement part of the solar cell array inspection system according to claim 6; and
the blocking diode that supplies the current from each string of the solar cell array to the measurement part.

19. A solar cell array inspection method causing a computer to execute:
a determination step of analyzing an I-V curve, which is an I-V curve of a solar cell array including a plurality of strings, measured when a current from each of the strings is input through a blocking diode, and determining whether a state of the solar cell array is an abnormal state in which at least one string has an abnormality; and
a notification step of notifying a user of a determination result of the state of the solar cell array according to the determination step.

20. A solar cell array inspection method causing a computer to execute:
a determination step of combining and analyzing I-V curves of strings of a solar cell array including a plurality of strings by addition and subtraction, and determining whether a state of the solar cell array is an abnormal state in which at least one string has an abnormality; and
a notification step of notifying a user of the determination result of the state of the solar cell array according to the determination step.
